(19) United States
(12) Patent Application Publication
(10) Pub. No.: US 2015/0187707 A1
(43) Pub. Date: Jul. 2, 2015

(54) Biometric Image Sensor Packaging and Mounting

(71) Applicant: Synaptics Incorporated, San Jose, CA (US)

(72) Inventors: Young Seen LEE, San Jose, CA (US); Brett DUNLAP, San Jose, CA (US); Paul WICKBOLDT, San Jose, CA (US)

(21) Appl. No.: 14/659,026

(22) Filed: Mar. 16, 2015

Related U.S. Application Data
(63) Continuation-in-part of application No. 14/050,012, filed on Oct. 9, 2013.
(60) Provisional application No. 61/953,210, filed on Mar. 14, 2014.
(60) Provisional application No. 61/713,550, filed on Oct. 14, 2012.
(60) Provisional application No. 61/754,287, filed on Jan. 18, 2013.

(51) Int. Cl. H01L 23/00; G01N 27/22; H01L 21/02; G06K 9/00

(52) U.S. Cl. CPC H01L 23/562; G06K 9/0002; G01N 27/22; H01L 21/02118; H01L 21/02112

(57) ABSTRACT

A method for providing a biometric sensor arrangement includes: forming the biometric sensor comprising sensor elements and a controller IC disposed on a substrate; at least partially enclosing the biometric sensor within a molded body; depositing capping material on the biometric sensor to form a capping layer on the biometric sensor; embossing the capping material of the capping layer; and curing the capping layer.

### CROSS REFERENCE TO RELATED APPLICATIONS

This application claims priority to U.S. provisional patent application Ser. No. 61/953,210 to Young Seen Lee, et al., filed on Mar. 14, 2014, entitled “BIOMETRIC IMAGE SENSOR PACKAGING AND MOUNTING,” the entire contents of which are herein incorporated by reference.

This application is also a continuation-in-part of U.S. non-provisional patent application Ser. No. 14/050,012 to Brett Dunlap, et al., filed on Oct. 9, 2013, entitled “FINGERPRINT SENSOR BUTTON COMBINATIONS AND METHODS OF MAKING SAME,” U.S. publication number US2014/0103943, the entire contents of which are herein incorporated by reference. U.S. non-provisional patent application Ser. No. 14/050,012 claims priority to provisional patent application Ser. No. 61/713,550, filed on Oct. 14, 2012, and provisional patent application Ser. No. 61/754,287, filed on Jan. 18, 2013.

### FIELD

This disclosure generally relates to electronic sensors, and more particularly to fingerprint sensor packages.

### BACKGROUND

Since its inception, fingerprint sensing technology has revolutionized biometric identification and authentication processes. In most cases, a single fingerprint can be used to uniquely identify an individual in a manner that cannot be easily replicated or imitated. The ability to capture and store fingerprint image data in a digital file of minimal size has yielded immense benefits in fields such as law enforcement, forensics, and information security.

Fingerprint sensors utilize a variety of different sensing technologies, such as capacitive, optical, ultrasonic, resistive, and others, depending on a variety of considerations. Typically, fingerprints sensors use one of these sensing technologies to capture an image of a fingerprint when a user swipes or places their finger on an input surface. In many instances, it is important for the sensor elements below to be protected from repeated user touches or other environmental factors while providing a cosmetically appealing look and feel for the user. At the same time, it is often desirable to protect the sensor elements without increasing the distance between the sensor elements and the input surface too much, as this can negatively impact signal strength, particularly where capacitive sensing technologies are used to capture small ridge and valley features of a fingerprint.

### BRIEF DESCRIPTION OF THE DRAWINGS

A better understanding of the features and advantages of the present invention will be obtained by reference to the following detailed description that sets forth illustrative embodiments, in which the principles of the invention are utilized, and the accompanying drawings of which:

FIGS. 1(a)-(c) are schematic diagrams illustrating a fingerprint image sensor arrangement according to an embodiment of the disclosed subject matter;

FIG. 2(a)-(c) are schematic diagrams illustrating another fingerprint image sensor arrangement according to an embodiment of the disclosed subject matter;

FIG. 3(a)-(c) are schematic diagrams illustrating yet another fingerprint image sensor arrangement according to an embodiment of the disclosed subject matter.

While the disclosure will be described in connection with certain preferred embodiments, there is no intent to limit it to those embodiments. On the contrary, the intent is to cover all alternatives, modifications and equivalents as included within the spirit and scope of the disclosure as defined by the appended claims.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

Among other things, the present disclosure describes sensor packages and techniques for packaging sensors, including fingerprint sensors.

Embodiments of the present disclosure use exposed molding technology (sometimes referred to as “exposed die molding”). Further, in certain embodiments, exposed molding technology can be used to encapsulate sensor elements without encapsulating a semiconductor die or integrated circuit (IC). This allows molding around the sidewalls of the sensor while leaving the sensing elements exposed from the top.

A protective layer at the exposed area may be used in order to protect the sensing elements from the environment, and hide the sensing elements for cosmetic effect. Among other things, the present disclosure describes an approach to packaging the sensor elements by using an imprinted capping layer over the sensor elements of a biometric sensor in an exposed molding package. The capping layer may be imprinted (sometimes referred to herein as “embossed”) over the sensor elements, allowing the capping layer to hide seams that may result from the sensor elements. The capping layer may be imprinted over the sensor elements using a separate molding operation and separate mold than that used to form sidewalls of the exposed die molding. The mold used to imprint the capping layer may have an interior surface with a pattern that matches a desired input surface for the user of the sensor. For example, it may be a smooth surface, a textured pattern that uniformly diffuses light at its surface for a smooth appearance, or some other pattern. The discrete operation used to form the imprinted capping layer may allow it to be made thin enough for the sensor elements below to sense through the capping layer with sufficient signal strength. Additionally, since the upper surface of the capping layer can be made to match the interior of the mold used to imprint the layer over the sensor, the upper surface of the capping layer does not have to conform to the geometry of the sensor pattern below.

Thus, the imprinting that is performed over the sensor elements according to embodiments of the present disclosure, which essentially utilize a second molding step after the main molded body is formed with an exposed upper surface opening, allows for a relatively thin capping layer to be formed at the top surface of the package that provides a smooth or otherwise customized interface that does not depend on the topography of the sensor elements below the capping layer. Further, because imprinting materials may be cured to be relatively hard, the imprinting process provides relatively stronger protection with better durability even for a capping layer that is relatively thin. This process is also advantageous with respect to the ease and cost of manufacturing, and it avoids potential shortcomings of conventional techniques for forming the sensor package, such as spray coating (conformal to the physical topography of the sensor elements) and overmolding (requiring a costly, iterative grinding-down process).

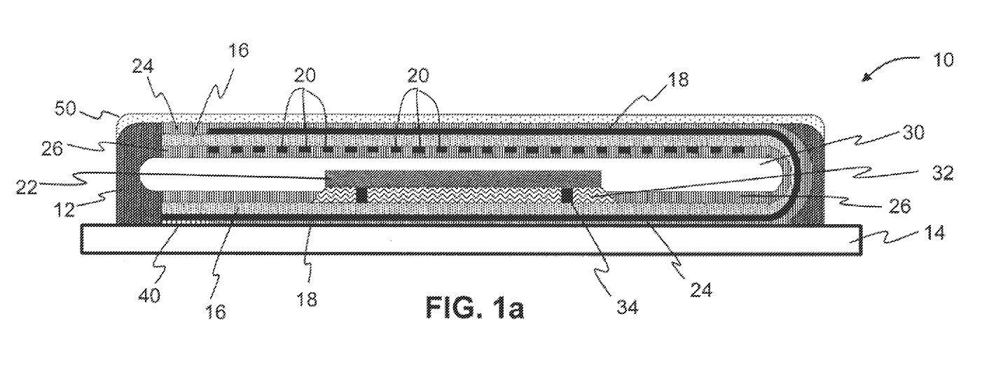

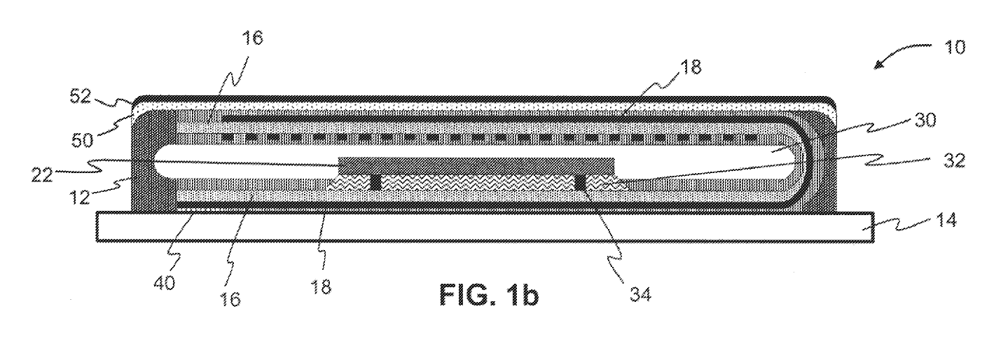

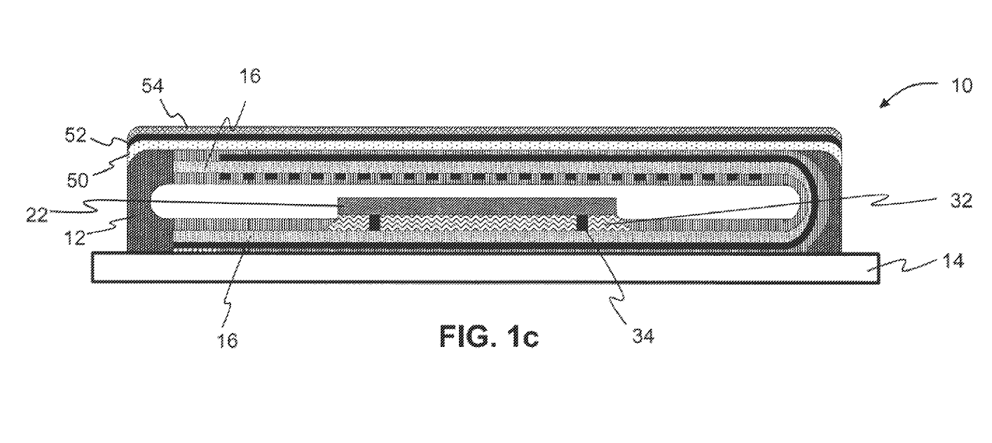

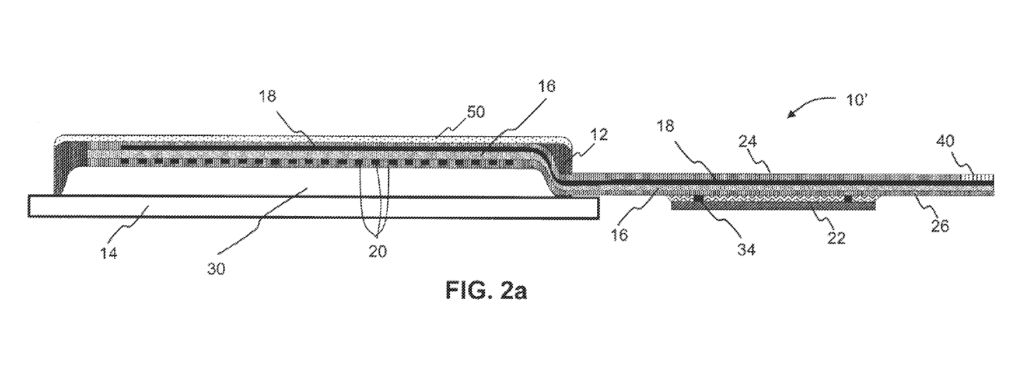

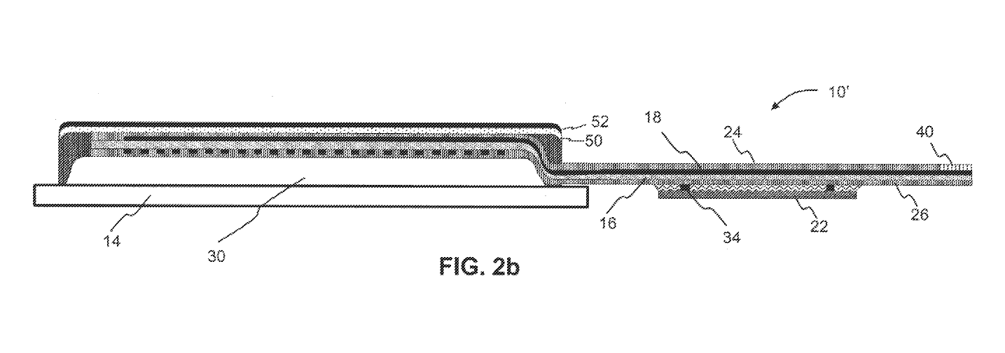

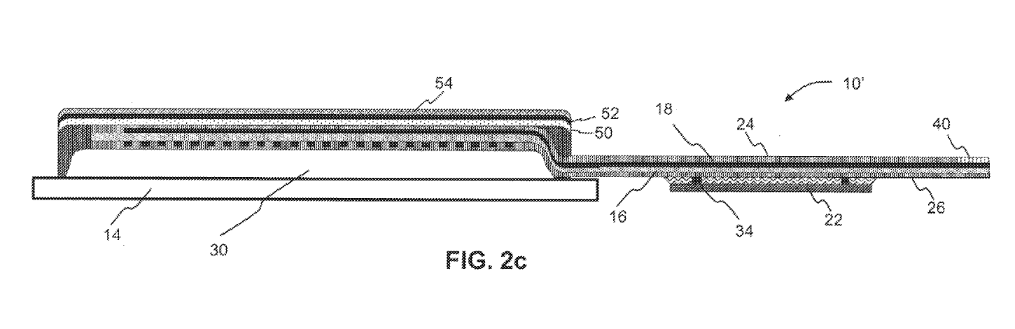

Turning now to the figures, in various embodiments of the disclosed subject matter, a biometric sensor 10 is packaged for assembly within or into an electronic system (e.g. a computer, tablet computer, cellular phone, entertainment device, and the like). One embodiment of a process for packaging such a biometric sensor 10 is, e.g., “chip on flex” (“COF”), e.g., for the type of biometric sensor 10 as shown in FIGS. 1(a)-(c) or 10′ as shown in FIGS. 2(a)-(c). In this embodiment, a COF fingerprint image sensor can have the image sensor tracer elements 18, 20 (e.g. capacitive pick up and drive plates) disposed on a flexible substrate 16 (e.g. a polyimide film).

In the illustrated examples shown in FIGS. 1(a)-(c) and 2(a)-(c), the flexible substrate 16 is shown as a single layer substrate, and the image sensor tracer elements 18, 20 are formed on both sides of the single layer. Specifically, in the illustrated example, the image sensor tracer elements 18 are disposed on one side of the layer and the image sensor tracer elements 20 are disposed on the opposite side of the same layer. However, other configurations are possible. For example, the flexible substrate 16 may be a single layer or multiple layers, and the image sensor tracer elements 18, 20 may be formed on one or both sides of the single layer, or the image sensor tracer elements 18 may be disposed on one of the multiple layers while the sensor elements 20 are disposed on another layer of the multiple layers. A fingerprint image sensor controller integrated circuit (IC) 22 (i.e., a fingerprint image sensor controller and/or image processor), such as a microprocessor integrated circuit or a microcontroller integrated circuit or controller integrated circuit, such as an application specific integrated circuit (“ASIC”), may be communicatively coupled to the sensor leads on the substrate 16, e.g., through solder bumps 34 surrounded by an underfill 32. In the illustrated embodiment, the integrated circuit 22 is mounted to the substrate 16, and the bumps 34 are used to connect the integrated circuit 22 to the image sensor tracer elements 18, 20.

As can be seen with reference to FIGS. 1(a)-(c) chip on flex (“COF”) fingerprint image sensor arrangement 10, may be formed utilizing a molded body 12, which can contain, e.g., on one surface of an interposer, e.g., a relatively rigid printed circuit board (“PCB”) 14, a flexible substrate 16, for the COF mounting arrangement. The flexible substrate 16 may be formed with an upper metallization tracer elements layer (containing image sensor tracer elements 18) and a lower metallization tracer elements layer (containing image sensor tracer elements 20), by way of example only with the upper metallization tracer layer forming a single or dual line drive or pickup element and the lower metallization tracer elements of the lower metallization tracer elements layer forming a plurality of the opposite form pick-up or driver capacitive gap sensor array tracer elements. It will be understood by those in the art that, especially for single line or multiple line 1D tracer element arrays, the drive tracer elements and pick-up tracer elements may be formed on the same surface of the flexible substrate 16 with the capacitive gap being in a generally horizontal direction, as oriented in FIG. 1(a)-(c), 2(a)-(c) or 3(a)-(c). It will also be understood that, in FIGS. 1 (a)-(c), one of a plurality of upper metallization layer tracer elements (drive elements or pick-up elements) may form a 2D array of tracer elements, e.g., in a 2D fingerprint sensor array, with the capacitive gap being vertical between respective drive and pick-up elements in each given array pixel location. The upper metallization sensor element trace(s) can be protected from, e.g., structural damage and electrostatic discharge, e.g., by a protective coating 24. The lower metallization sensor element traces can be protected from, e.g., structural damage and electrostatic discharge, e.g., by a lower metallization protective coating 26.

It can be seen in the biometric sensor 10 of FIGS. 1 (a)-(c) that the fingerprint image sensor controller IC 22 can be structurally protected by a relatively rigid insert 30, which can, e.g., have a recess into which the fingerprint image sensor controller IC 22 can fit when mounted on the flexible substrate 16. In the embodiment illustrated in FIGS. 1(a)-(c), the sensor arrangement has solder bumps 34 for electrically connecting the IC 22 with, e.g., the image sensor tracer elements 18, 20 formed in one or both sides of the flexible substrate 16, and underfill 32 surrounds the bumps and fills a remaining space between the IC 22 and the underlying substrate 16. An adhesive layer or strip or the like 40, such as an anisotropic conductive film (“ACF”), can be utilized to attach the flexible substrate 16, e.g., along one edge of the flexible substrate 16, to the PCB 14.

It will be understood by those in the art that the biometric sensor 10 may be manufactured by first attaching the COF fingerprint image sensor flexible substrate 16 to the relatively rigid interposer (PCB) 14, having the IC 22 mounted on the flexible substrate 16 and the upper and lower metallization layers 18, 20 and protective coatings 24, 26 formed on those metal layers 18, 20. The structural support insert 30 may then be placed over the IC 22 and the flexible substrate 16 may be folded back over itself and the insert 30. The assembly may then be placed in a suitable plastic molding apparatus and a molded body 12, e.g., made of plastic, formed around the assembly to seal the COF IC arrangement on the PCB 14.

In the illustrated examples of FIGS. 1(a)-(c), the image sensor tracer elements 18, 20 and the sensor IC 22 are disposed within the molded body 12. However, it is also possible for the image sensor tracer elements 18, 20 to be disposed within the molded body 12 while the sensor IC 22 is disposed outside of the molded body, an example of which is shown in FIGS. 2(a)-(c). The COF fingerprint sensor arrangement of biometric sensor 10′ illustrated in FIGS. 2(a)-(c) may be formed in a similar way as the arrangement of biometric sensor 10 in FIGS. 1 (a)-(c), with the exception that the flexible substrate 16 is supported on the PCB 14 prior to the molding operation by the insert 30 and the flexible substrate 16 with the COF IC 22 mounted on the flexible substrate 16 extend through and externally out of the molded body 12. It will be understood that the COF IC 22 may be mounted on either side of the flexible substrate 16 in the region external to the molded body 12.

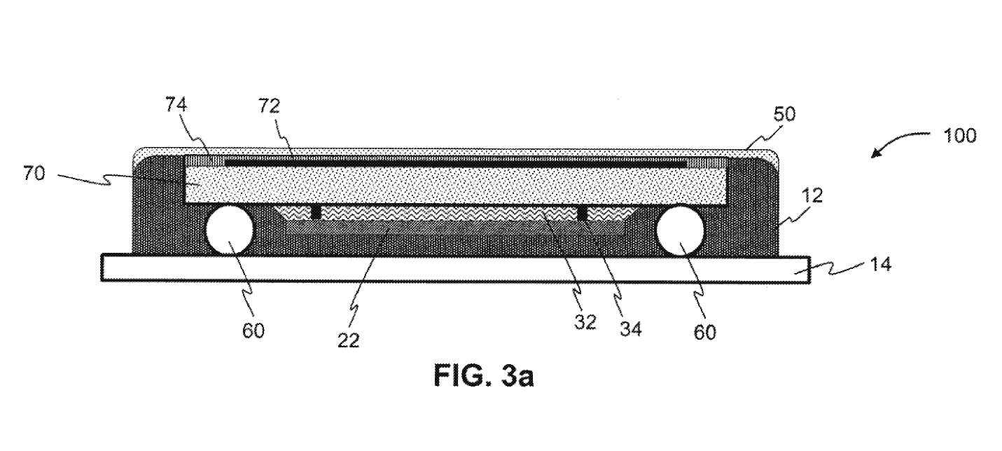

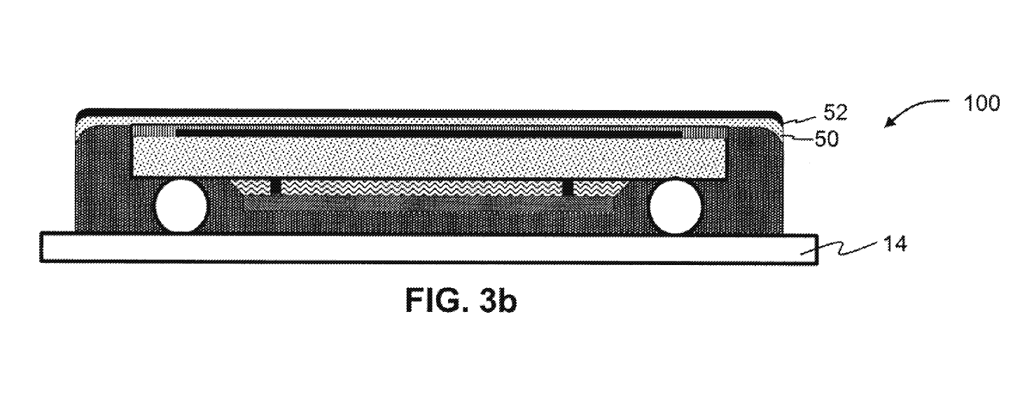

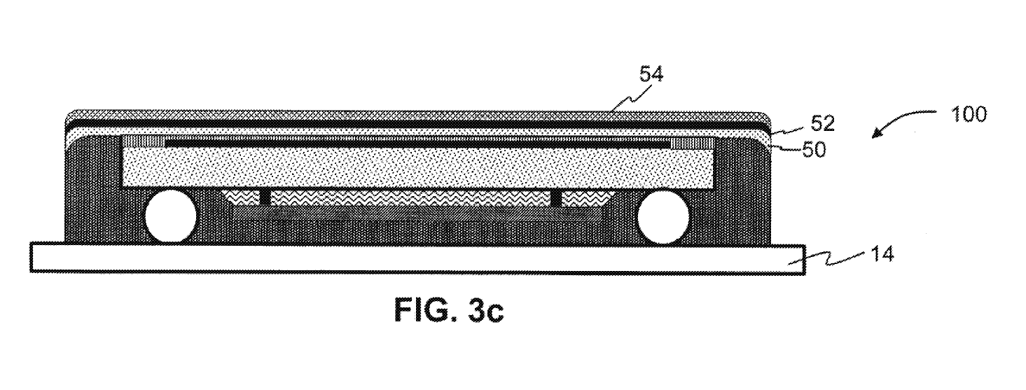

In another embodiment, illustrated in FIGS. 3(a)-(c), a process for packaging a Ball Grid Array (BGA) Sensor Package is shown. FIGS. 3(a)-(c) illustrate an embodiment of a fingerprint image sensor 100. Other examples of BGA sensor packages are shown and described in U.S. non-provisional patent application Ser. No. 14/050,012 to Brett Dunlap, et al., filed on Oct. 9, 2013, entitled “FINGERPRINT SENSOR BUTTON COMBINATIONS AND METHODS OF MAKING SAME,” U.S. publication number US2014/0103943, the entire contents of which are herein incorporated by reference. In some embodiments, the fingerprint image sensor 100 of FIGS. 3(a)-(c) may have features in common with one or more of the BGA sensor packages described in that publication. For example, in some embodiments, the BGA substrate 70 of FIGS. 3(a)-3(c) may be a multi-layer laminate, with sensor traces formed on multiple layers of the substrate and formed to fan out from the connected IC, as shown and described in more detail in that publication. However, in other embodiments, a different single or multi-layer substrate may be used. Preferably, for the BGA style package of FIGS. 3(a)-(c), the BGA substrate 70 is a rigid substrate.

In the arrangement of FIGS. 3(a)-(c), a fingerprint image sensor controller IC 22 can be mounted and packaged in or on a fingerprint image sensor ball grid array substrate 70, e.g., using solder bumps 34 surrounded by an underfill material 32. The package may have sensor tracer elements 72, e.g., covered with a protective coating 74. Such a BGA sensor package 100 may comprise sensor elements disposed on one side of the substrate 70 (e.g. a multi-layer laminate printed circuit board), e.g., with the IC 22 communicatively coupled to the sensor tracer elements 72 and disposed on a side of BGA substrate 70. In some embodiments, the IC 22 may be disposed on the same side or a different side of the substrate 70 as the sensor tracer elements 72. In the illustrated example, the IC 22 is disposed on the opposite side of the substrate as the sensor tracer elements 72.

Embodiments of the disclosed subject matter include processes for packaging a sensor (e.g., a COF sensor, BGA sensor, or the like) using an embossing or imprinting technique to form a capping layer over the sensor. This embossing or imprinting operation may be separate from a molding operation used to form the molded body 12.

It will be understood by those in the art that the molding material for forming the molded body 12 may be, e.g., any of a number of epoxy molding compounds, polycarbonate, Nylon or glass-fiber enforced Nylon, or any other suitable molding material, such as any of a number of other injection-moldable materials. The created mold may be configured to form sidewalls (e.g., as shown with respect to the molded body in FIGS. 1(a)-(c), 2(a)-(c), and 3(a)-(c)), leaving the upper/outer fingerprint image sensor traces protective surface, e.g., comprising a solder mask resist or polyimide film (where the user finger is placed or swiped) substantially exposed.

Then, according to aspects of the present disclosure, a capping layer 50, which may comprise a deposited protective coating or layer, such as a hardenable resin (e.g., a UV-curable resin), can be deposited onto the sensor assembly surface. This layer may be separately applied after the molding operation or may be, e.g., pressed onto the top of the sensor assembly by the molding process. The capping layer 50 may comprise poly(methyl methacrylate), urethane acrylate/acrylate blend, an epoxy-based resin, or the like. The capping layer 50 material, may, e.g., during the molding process, be pressed under the mold, so as to conform to the mold and the sensor surface without any substantial unintentional demarcation lines.

In another embodiment, upon pressing the mold onto the sensor assembly, the capping layer 50 material may be cured (e.g. with ultraviolet light). After a sufficient cure of the capping layer material is achieved, e.g., the mold may be removed. The thickness of the resulting capped layer may thus be configured to be controlled by the mold structure, pressure, temperature, and the properties of the capping material 50, such as viscosity and curing properties.

In various embodiments, the mold (not shown) used to imprint the capping layer over the sensor may comprise a soft mold or hard mold. The mold may be a master mold used for multiple parts. The mold may comprise an embossment reflected on the upper surface of the layer 50 of the packaged biometric sensor arrangement, depending on the desire for a smooth surface, or one with texture, or other features formed on the surface, e.g., ergonomic guides or like structures.

In various embodiments, the sensor arrangement and its packaging can further be processed to provide a decorative layer 52 and/or a hard coat layer 54, e.g. by using a spray, screen printing, dip or another UV-embossing process. The decorative layer 52 and/or the hard coat layer 54 may each be opaque or transparent, and may each conceal or diminish any visual marking on the upper surface of the sensor. In some embodiments, the decorative layer 52 may introduce a new visual pattern such as a logo or decoration. This decorative layer 52 may be configured based on the durability, location and decoration required. The sensor package surface may also be modified by grinding, polishing, or etching, e.g., to change the surface texture or appearance.

In the examples illustrated in FIGS. 1-3, the imprinted capping layer is disposed over the sensor elements, the decorative layer is disposed over the capping layer, and the hard coat is disposed over the decorative layer. In these examples, the decorative layer may be an opaque color layer, and the hard coat may be disposed over the decorative layer to protect the color layer. In certain embodiments, the decorative layer may instead be formed between the capping layer and the sensor elements, so that the capping layer is imprinted over the sensor elements and the decorative layer. In these embodiments, the capping layer may protect the decorative layer and allow the hard coat to be omitted. Since the hard coat may be omitted, this may provide a yet thinner protective coating over the sensor elements, which may beneficially improve the signal to noise ratio of the sensor.

In some embodiments, the capping layer 50 may comprise a high dielectric material or high dielectric particles which increase the permittivity between the sensor element traces and an input object on the top surface of the biometric sensor arrangement package (i.e., the finger being sensed).

In some embodiments, the capping layer 50 may be deposited on the sides as well as the top of the sensor arrangement. In some embodiments, the additional decorative and/or hard coat layer may likewise be deposited on the side walls and the top surface.

It will be understood by those skilled in the art that, according to aspects of embodiments of the disclosed subject matter, the capping layer 50 and other layers 52, 54, e.g., may be utilized to form a planarization layer over the fingerprint sensor arrangement, e.g., as an embossed/imprinted coating method. By doing so, as an example, the desire for a seamless surface over a fingerprint image sensor arrangement that has, e.g., a maximum cover layer thickness of tens of microns can be achieved. This may be advantageous for sensors having sensor elements in the form of conductive traces formed on a substrate (as opposed to semiconductor die sensor elements), as these are more likely to have a physical topography that can be seen or felt through a thin protective layer if the imprinting technique of the present disclosure is not used.

It will be understood by those skilled in the art that methods and apparatuses for providing a biometric sensor arrangement are disclosed, which may, for example, include forming the biometric sensor comprising sensor elements and a controller IC disposed on a substrate; at least partially enclosing the biometric sensor within a molded body; depositing capping material on the biometric sensor to form a capping layer on the biometric sensor; embossing the capping material of the capping layer; and curing the capping layer. The methods and apparatuses may further utilize at least one of a ball grid array (“BGA”) type package and a chip on flex (“COF”) type IC mounting. The substrate of the biometric sensor arrangement may comprise a flexible substrate comprising one of a polyimide film or a flexible printed circuit board. The mold material may comprise a molding compound. For example, the mold material may comprise an epoxy molding compound, polycarbonate, Nylon, or glass-fiber enforced Nylon. The methods and apparatuses may further comprise forming the mold to at least partially cover the biometric sensor arrangement, comprising forming the sidewalls of the biometric sensor arrangement.

The capping layer may include one of poly(methyl methacrylate), urethane acrylate/acrylate blend, and an epoxy-based resin. A thickness of the capping layer may be less than 200 microns. The thickness of the capping layer may be configured by one of the mold structure, mold pressure and mold temperature or by one of the viscosity of the capping material and curing properties of the capping material. The mold may comprise one of a soft mold and a hard mold, and may comprise one of a smooth surface or a textured pattern. The capping layer may comprise a high dielectric material configured to increase the permittivity between the sensor and an object being sensed.

While certain embodiments described above have been described with respect to fingerprint sensors, the principles described herein may be implemented with respect to other types of sensors as well, including other biometric sensors and other capacitive sensors. In addition, while the illustrated examples depict sensor elements in the form of conductive traces connected to an IC, in other implementations it is possible to form sensor elements in a semiconductor die, with the semiconductor die including or not including the sensor controller IC.

While embodiments of the present invention have been shown and described herein, such embodiments are provided by way of example only. Numerous variations, changes, and substitutions may be contemplated by those skilled in the art without departing from the invention. It should be understood that various alternatives to the embodiments of the invention described herein may be employed in practicing the invention.

The terms used in the claims should be understood as having the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C

1. A method for providing a biometric sensor arrangement, the method comprising:
forming the biometric sensor comprising sensor elements and a controller integrated circuit (IC) disposed on a substrate;
at least partially enclosing the biometric sensor within a molded body;
depositing capping material on the biometric sensor to form a capping layer on the biometric sensor;
embossing the capping material of the capping layer; and
curing the capping layer.

2. The method of claim 1, wherein the biometric sensor comprises at least one of a ball grid array (“BGA”) type package and a chip on flex (“COF”) type IC mounting.

3. The method of claim 1, wherein the substrate is a flexible substrate comprising a polyimide film and/or a flexible printed circuit board.

4. The method of claim 1, wherein mold material of the molded body comprises a molding compound, polycarbonate, Nylon, and/or glass-fiber enforced Nylon.

5. The method of claim 1, wherein at least partially enclosing the biometric sensor within the molded body comprises: forming sidewalls of the biometric sensor arrangement.

6. The method of claim 1, wherein the capping layer comprises poly(methyl methacrylate), urethane acrylate/acrylate blend, and/or an epoxy-based resin.

7. The method of claim 1, wherein a thickness of the capping layer is less than 200 microns.

8. The method of claim 1, wherein a thickness of the capping layer is based on mold structure, mold pressure and/or mold temperature.

9. The method of claim 1, wherein a thickness of the capping layer is based on viscosity of the capping material and/or curing properties of the capping material.

10. The method of claim 1, wherein the molded body comprises a soft mold and/or a hard mold, and wherein the molded body comprises a smooth surface and/or a textured pattern.

11. The method of claim 1, wherein the capping layer comprises a high dielectric material configured to increase permittivity between the biometric sensor and an object being sensed.

12. A biometric sensor arrangement, comprising:
a biometric sensor, the biometric sensor comprising:
a substrate,
sensor elements disposed on the substrate, and
a controller integrated circuit (IC) disposed on the substrate;
a molded body at least partially enclosing the biometric sensor; and
a capping material disposed on the biometric sensor forming a capping layer on the biometric sensor, wherein the capping material is embossed in the capping layer, and wherein the capping layer is cured.

13. A biometric sensor arrangement, comprising:
a biometric sensor, the biometric sensor comprising:
sensor elements in communication with a controller integrated circuit (IC);
a molded body at least partially enclosing the biometric sensor, the molded body having an opening corresponding to the sensor elements of the biometric sensor; and
a capping layer disposed on the biometric sensor at the opening, the capping layer comprising a capping material imprinted over the sensor elements.

14. The biometric sensor arrangement of claim 13, further comprising:
a decorative layer disposed over the sensor elements.

15. The biometric sensor arrangement of claim 14, further comprising:
a hard coat disposed over the sensor elements,
wherein the decorative layer is disposed over the capping layer and the hard coat is disposed over the decorative layer.

16. The biometric sensor arrangement of claim 14, wherein the capping layer is disposed over the decorative layer.

17. The biometric sensor arrangement of claim 13, wherein the capping layer has a smooth upper surface.

18. The biometric sensor arrangement of claim 13, wherein the capping layer has a textured upper surface.

19. The biometric sensor arrangement of claim 13, wherein the capping layer comprises:
a lower surface facing towards the sensor elements, the lower surface having a pattern conforming to a pattern formed by the sensor elements, and
an upper surface facing away from the sensor elements, the upper surface having a pattern different from the pattern formed by the sensor elements.

20. The biometric sensor arrangement of claim 13, wherein the capping layer comprises a cured resin.

21. The biometric sensor arrangement of claim 13, wherein the capping layer comprises poly(methyl methacrylate), urethane acrylate/acrylate blend, and/or an epoxy-based resin.

22. The biometric sensor arrangement of claim 13, wherein the sensor elements and the controller IC are disposed within the molded body.

23. The biometric sensor arrangement of claim 13, wherein the sensor elements are disposed within the molded body and the controller IC is disposed outside of the molded body.

24. The biometric sensor arrangement of claim 13,
wherein the biometric sensor further comprises a substrate, and
wherein the sensor elements and the controller IC are disposed on the substrate.

25. The biometric sensor arrangement of claim 24,
wherein the sensor elements include conductive traces formed on the substrate,
wherein the conductive traces include capacitive drive and pickup plates configured to capture an image of a fingerprint, and
wherein the controller IC is mounted to the substrate and connected to the conductive traces.
